(19) United States
(12) Patent Application Publication
(10) Pub. No.: US 2005/0167767 A1
(43) Pub. Date: Aug. 4, 2005

(54) Semiconductor apparatus and manufacturing method of the same

(75) Inventor: Yasushi Akasaka, Ibaraki (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Semiconductor Leading Edge Technologies , Inc., Tsukuba-shi (JP)

(21) Appl. No.: 11/043,962

(22) Filed: Jan. 28, 2005

(30) Foreign Application Priority Data
Jan. 30, 2004 (JP) 2004-024301

(51) Int. Cl. H01L 29/45

(52) U.S. Cl. 257/410

(57) ABSTRACT

A semiconductor apparatus comprises a first semiconductor device and a second semiconductor device. The first semiconductor device includes: a semiconductor layer having a p-type channel area; an n-type source area, and an n-type drain area; a first gate insulating film provided on the p-type channel area; and a first gate electrode provided on the first gate insulating film containing a first metallic element and nitrogen. The second semiconductor device includes: a semiconductor layer having an n-type channel area, a p-type source area, and a p-type drain area; a second gate insulating film provided on the n-type channel area; and a second gate electrode provided on the second gate insulating film containing a second metallic element and nitrogen. A nitrogen content of the second gate electrode is higher than a nitrogen content of the first gate electrode.

### CROSS-REFERENCE TO RELATED APPLICATIONS

This application is based upon and claims the benefit of priority from the prior Japanese Patent Application No. 2004-024301, filed on Jan. 30, 2004; the entire contents of which are incorporated herein by reference.

### BACKGROUND OF THE INVENTION

The present invention relates to a semiconductor apparatus and a manufacturing method of it and more particularly to a semiconductor apparatus having an n-type MISFET and a p-type MISFET and a manufacturing method of it.

In correspondence to refinement of semiconductor integrated circuit apparatuses, MIS (metal-insulator-semiconductor) type semiconductor devices are also to be made smaller in size. To realize a 65-nm node which is a target of next generation semiconductor apparatuses, a gate insulating film of a thin film having an oxide film converted film thickness (EOT: equivalent oxide thickness) of as thin as 1.2 nm and a gate leak current (Jg) of as low as 30 A/cm² is required. A method for using a plasma oxide film for an oxide film as a base and nitriding it in a radical mode has been disclosed. Furthermore, to reduce damage to a substrate, a process of nitriding a plasma oxide film at low energy in a low-pressure ion mode is disclosed and by applying this method, it is confirmed that a SiON film with an EOT of about 1.1 nm can be formed (D. Ishikawa et al., IEDM Tech. Dig., p. 869, 2002).

Furthermore, as a material of a gate insulating film capable of being made thin, hafnium oxide (HfO₂) based high dielectric (high-k) material is noticed. Namely, at present, as a gate electrode, polycrystalline Si or polycrystalline SiGe doped by P (phosphorus), As (arsenic), or B (boron) in high concentration is used. In the case of doped poly-Si and poly-SiGe, high thermal stability enables high-temperature activation process of the source/drain diffusion layer after gate electrode formation. Moreover, extremely fine pattern formation technique by reactive ion etching (RIE) is established.

However, when these materials are used and a transistor is turned on, a depletion layer is formed in the gate electrode and a parasitic capacity is generated in series with the channel capacity. By this depletion, the effective thickness of the gate insulating film in the inversion region is increased by about 0.6 nm, so that a problem arises that it cannot be ignored for the thickness of the gate insulating film. To solve it, an examination of replacement of polycrystalline Si or SiGe of the gate electrode with a metal causing no depletion is pursued.

In an LSI of a LOP (low operation power) type aiming at obtaining high driving current at a low supply voltage of about 1 V, to optimize the threshold voltage of the n-type MISFET and the threshold voltage of the p-type MISFET, for the n-type MISFET gate electrode, n⁺-type polysilicon (polycrystalline silicon) is used and for the p-type MISFET gate electrode, p⁺-type polysilicon is used. To adjust the threshold voltage of the transistor, there are two methods available such as a method using channel ion implantation and a method for changing the work function of the gate. The latter is a superior method because it can change only the threshold voltage without adversely affecting the performance of the transistor. Therefore, to obtain the same performance as that of the present transistor, it is desirable to use a metal having a work function close to n⁺-type polysilicon for the n-type MISFET gate electrode and use a metal having a work function close to p⁺-type polysilicon for the p-type MISFET gate electrode.

When a polysilicon electrode is to be used, by the ion implantation method, by doping As or P in the n-type area and doping B in the p-type area, a gate electrode having two kinds of work functions can be formed simply. However, when using a metal as a gate electrode, a gate electrode having a lower work function (close to n⁺-type polysilicon) has a higher reactivity, so that a problem arises that it is apt to react on the gate insulating film. On the other hand, a metal having a higher work function (close to p⁺-type polysilicon) has a lower reactivity, so that a problem arises that it is not sufficiently adhered to the gate insulating film and is apt to peel off.

### SUMMARY OF THE INVENITON

According to an aspect of the invention, there is provided a semiconductor apparatus comprising a first semiconductor device and a second semiconductor device, the first semiconductor device including: a semiconductor layer having a p-type channel area; an n-type source area, and an n-type drain area; a first gate insulating film provided on the p-type channel area; and a first gate electrode provided on the first gate insulating film containing a first metallic element and nitrogen, the second semiconductor device including: a semiconductor layer having an n-type channel area, a p-type source area, and a p-type drain area; a second gate insulating film provided on the n-type channel area; and a second gate electrode provided on the second gate insulating film containing a second metallic element and nitrogen, a nitrogen content of the second gate electrode being higher than a nitrogen content of the first gate electrode.

According to other aspect of the invention, there is provided a semiconductor apparatus comprising a first semiconductor device and a second semiconductor device, the first semiconductor device including: a semiconductor layer having a p-type channel area; an n-type source area, and an n-type drain area; a first gate insulating film provided on the p-type channel area; and a first gate electrode provided on the first gate insulating film containing a first metallic element and nitrogen, the second semiconductor device including: a semiconductor layer having an n-type channel area, a p-type source area, and a p-type drain area; a second gate insulating film provided on the n-type channel area; and a second gate electrode provided on the second gate insulating film containing a second metallic element and nitrogen, the first metallic element and the second metallic element being different.

According to other aspect of the invention, there is provided a manufacturing method of a semiconductor apparatus having a first semiconductor device in which a first gate electrode is provided on a p-type channel area via a first gate insulating film and a second semiconductor device in which a second gate electrode is provided on an n-type channel area via a second gate insulating film, comprising: forming the first gate electrode on the first gate insulating film by feeding a first metallic element and nitrogen; and forming the second gate electrode on the second gate insulating film by feeding a second metallic element and nitrogen, the step of forming the first gate electrode and the step of forming the second gate electrode being performed so that a nitrogen content of the second gate electrode becomes higher than a nitrogen content of the first gate electrode.

### BRIEF DESCRIPTION OF THE DRAWINGS

The present invention will be understood more fully from the detailed description given here below and from the accompanying drawings of the embodiments of the invention. However, the drawings are not intended to imply limitation of the invention to a specific embodiment, but are for explanation and understanding only.

In the drawings:

FIG. 1 is a schematic diagram showing the sectional structure of the essential section of the semiconductor apparatus relating to the embodiment of the present invention;

FIG. 2 is a flow chart showing a part of the manufacturing steps of the CMISFET of the embodiment;

FIG. 3 is a flow chart showing the process of forming the gate electrode 25 after forming the gate electrode 35;

FIGS. 4A through 4H are step sectional views representing a part of the forming process of the CMISFET according to the embodiment of the invention;

FIG. 5 is a graph showing the work functions of several gate electrode materials plotted for the heat of formation of oxide thereof;

FIG. 6A through 6D are step sectional views representing the forming process of the MISFET produced by way of trial in the experiment of the inventor and FIG. 6E is a flow chart representing the forming process;

FIG. 7 is a graph showing the relationship between V fb of MISFET using HfSiON and V fb of MISFET using SiON;

FIG. 8 is a graph showing the gate leak current (Jg) of n-type MISFET using HfSiON;

FIG. 9 is a graph showing the relationship between the EOT and the gate leak current Jg of MISFET using HfSiON;

FIG. 10 is a graph showing the roll-off characteristic of the threshold voltage Vₜₕ of MISFET;

FIG. 11 is a graph showing the subthreshold characteristic when ZrN and TiN are used as a gate electrode of MISFET with a gate length Lg of 80 nm using HfSiON;

FIG. 12 is a graph showing the results of X-ray diffraction evaluation (XRD) of titanium based samples;

FIG. 13 is a graph showing the results of X-ray diffraction evaluation of zirconium based samples;

FIG. 14 is a graph showing the C-V characteristic of n-type MISFET using Ti based and Zr based gate electrodes;

FIG. 15 is a graph showing the C-V characteristic of n-type MISFET using Ti based gate electrodes;

FIG. 16 is a graph showing the C-V characteristic of p-type MISFET using Ti based gate electrodes; and

FIG. 17 is a graph showing the C-V characteristic of p-type MISFET using Ti based and Zr based gate electrodes.

### DETAILED DESCRIPTION

Hereinafter, the embodiment of the present invention will be explained with reference to the accompanying drawings.

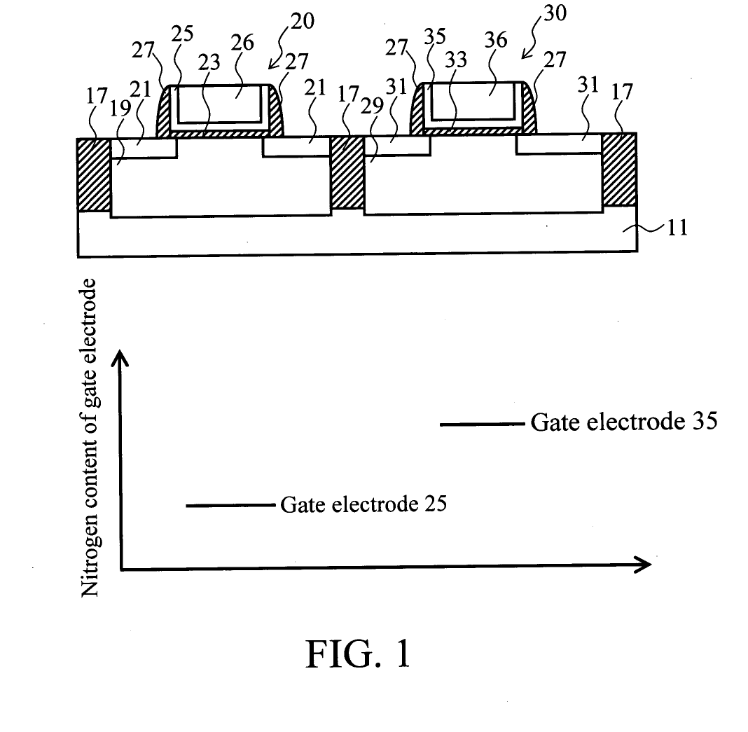

FIG. 1 is a schematic diagram showing the sectional structure of the essential section of the semiconductor apparatus relating to the embodiment of the present invention. Namely, the drawing is a cross section view of a complementary MISFET of the semiconductor apparatus shown in the drawing having an n-type MISFET (metal-insulator-semiconductor field effect transistor) 20 and a p-type MISFET 30.

The CMISFET of this embodiment has the n-type MISFET 20 and the p-type MISFET 30 which are formed on the same semiconductor substrate 11. On the surface of the semiconductor substrate 11, between these transistors, for example, an element isolation area 17 formed by embedding an insulating film in a groove is formed.

The n-type MISFET 20 is formed on a p-type well 19 on the surface of the semiconductor substrate 11. Namely, the n-type MISFET 20 is formed on the surface of the p-type well 19 and has a pair of n-type source/drain areas 21 forming a junction with the p-type well 19. Further, the n-type MISFET 20 has a gate insulating film 23 and a gate electrode 25 which are held by the pair of n-type source/drain areas 21 and are sequentially formed on the semiconductor substrate 11. The gate electrode 25 includes nitrogen and a metallic element. On the gate electrode 25, for example, an embedded electrode 26 composed of tungsten (W) is provided when necessary.

On the other hand, on an n-type well 29 which is provided on the surface of the semiconductor substrate 11, the p-type MISFET 30 is formed. The p-type MISFET 30 is formed on the surface of the n-type well 29 and has a pair of p-type source/drain areas 31 forming a junction with the n-type well 29. Further, the p-type MISFET 30 has a gate insulating film 33 and a gate electrode 35 which are held by the pair of p-type source/drain areas 31 and are sequentially formed on the semiconductor substrate 11. The gate electrode 35 also includes nitrogen and a metallic element. On the gate electrode 35, for example, an embedded electrode 36 composed of tungsten (W) is provided.

Further, the MISFETs 20 and 30 shown in FIG. 1 respectively have a gate side wall insulating film 27, though the insulating films may be omitted. Further, a drawing of the surface perpendicular to the cross sectional view shown in FIG. 1 (the section perpendicular to the paper surface of FIG. 1) and its explanation will be omitted because it is common to CMISFET and is widely known by those who are skilled in the art in the field of the present invention.

And, in the present invention, as a material of the gate electrodes 25 and 35, a nitride of the IV a group metal such as titanium (Ti) or zirconium (Zr) is used. Furthermore, according to a first aspect of the present invention, the amounts of nitrogen (N) contained in the gate electrodes 25 and 35 are not the same. Namely, as shown in the graph drawn in FIG. 1, the content of nitrogen in the gate electrode 35 of p-type MISFET is higher than the content of nitrogen in the gate electrode 25 of n-type MISFET. When the balance in the content of nitrogen between the gate electrode 25 and 35 is adjusted like this, the threshold voltages of the n-type MISFET 20 and the p-type MISFET 30 can be set on the same level.

On the other hand, according to a second aspect of the invention, the metal elements which are used for the gate electrodes 25 and 35 are not the same. More specifically, as will be explained later in more detail, ZrNₓ may be used for the gate electrode 25 of the n-type MISFET and TiN_{y} may be used for the gate electrode 35 of the p-type MISFET. In this case, the amounts of nitrogen (N) contained in the gate electrodes 25 and 35 are not necessarily different as shown in FIG. 1.

Namely, as a material of the gate electrode 25 of n-type MISFET 20, it is desirable to use a material having a work function close to that of n⁺-type polysilicon (polycrystalline silicon)(4.03 eV). On the other hand, as a material of the gate electrode 35 of p-type MISFET 30, it is desirable to use a material having a work function close to that of p⁺-type polysilicon (5.15 eV).

On the other hand, the inventor found that in a metal nitride, when the nitrogen content is low, a work function close to n⁺-type polysilicon is obtained and when the nitrogen content is high, a work function close to p⁺-type polysilicon is obtained. This trend is conspicuous, for example, in a nitride of the IV a group element such as titanium (Ti) or zirconium (Zr). Namely, in titanium nitride (TiN) or zirconium nitride (ZrN), when the nitrogen content is low, a work function close to n⁺-type polysilicon is obtained and when the nitrogen content is high, a work function close to p⁺-type polysilicon is obtained. In these nitrides, it is found that according to the nitrogen content, the work function is changed by 0.5 to 0.6 electron volts (eV) or so. And, when the work function is changed by 0.45 electron volts or more, an optimal gate electrode can be realized respectively in the n-type MISFET and p-type MISFET.

On the other hand, it was found that a gate electrode 25 having a work function close to that of n⁺-type polysilicon and a gate electrode 35 having a work function close to that of p⁺-type polysilicon may be realized by using metal nitrides and by selecting different metal elements for these gate electrodes 25 and 35.

The adjustment of the nitrogen content for the gate electrodes 25 and 35 can be realized by controlling the flow rate ratio of the raw materials at the forming step thereof.

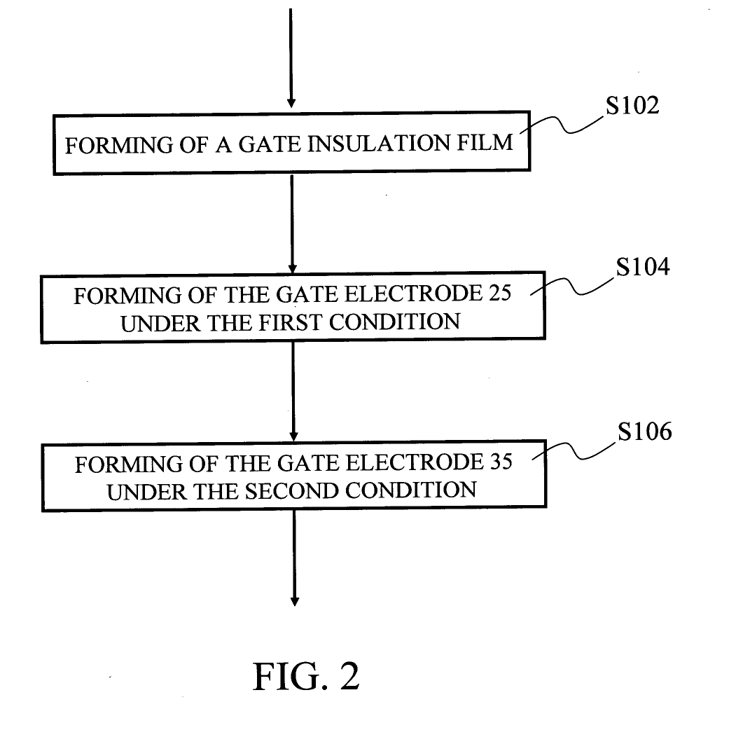

FIG. 2 is a flow chart showing a part of the manufacturing steps of the CHISFET of this embodiment. Namely, the gate insulating films 23 and 33 are formed at Step S102, and then the gate electrode 25 is formed under the first condition at Step S104. Thereafter, the gate electrode 35 is formed under the second condition at Step S106.

As described in detail later, as a forming method of the gate electrodes 25 and 35, there are the CVD (chemical vapor deposition) method and the reactive sputtering method available.

In the CVD method, for example, first source gas containing a metallic element and second source gas containing nitrogen are supplied onto a wafer to generate a decomposition reaction such as heat decomposition, thus a metallic nitride can be formed. In this case, the flow rate ratio between the first source gas and the second source gas is controlled. Namely, as the first condition at Step S104, the ratio of the flow rate of the second source gas to the flow rate of the first source gas is reduced. On the other hand, as the second condition at Step S106, the ratio of the flow rate of the second source gas to the flow rate of the first source gas is increased. By doing this, the amount of nitrogen contained in the gate electrode 25 of n-type MISFET can be reduced and the amount of nitrogen contained in the gate electrode 35 of p-type MISFET can be increased.

On the other hand, in the reactive sputtering method, in an atmosphere containing nitrogen, a target containing a metallic element is sputtered, thus a nitride of the metal is formed on a wafer. In this case, by controlling the nitrogen concentration contained in the atmosphere, the nitrogen content of a gate electrode to be formed can be adjusted. Namely, under the first condition (Step S104), the nitrogen concentration in the sputtering atmosphere is reduced and under the second condition (Step S106), the nitrogen concentration in the sputtering atmosphere is increased.

Further, the forming order of the gate electrodes 25 and 35 may be reversed.

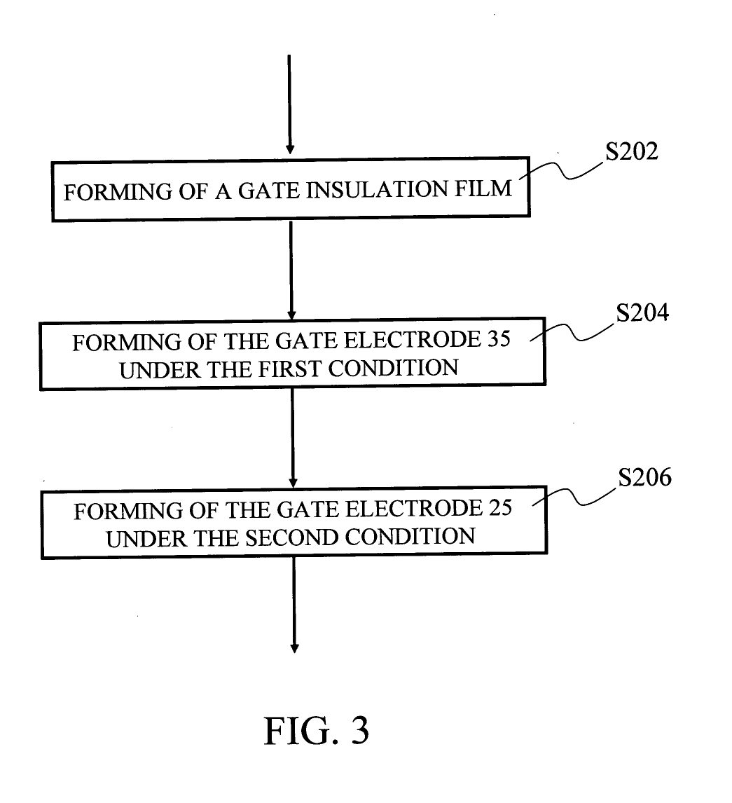

FIG. 3 is a flow chart showing the process of forming the gate electrode 25 after forming the gate electrode 35. In this case, needless to say, the contents of the first condition and the second condition are inverse to those shown in FIG. 2.

Next, a detailed example of the manufacturing method of the CMISFET according to the embodiment of the invention will be explained. According to the embodiment of the invention, the metal elements and/or the contents of nitrogen are different between the two gate electrodes of the CMISFET. Such a CMISFET may be fabricated by applying a method disclosed by Samavedam et al. (IEDM Tech. Digest, 2002, p. 443), for example.

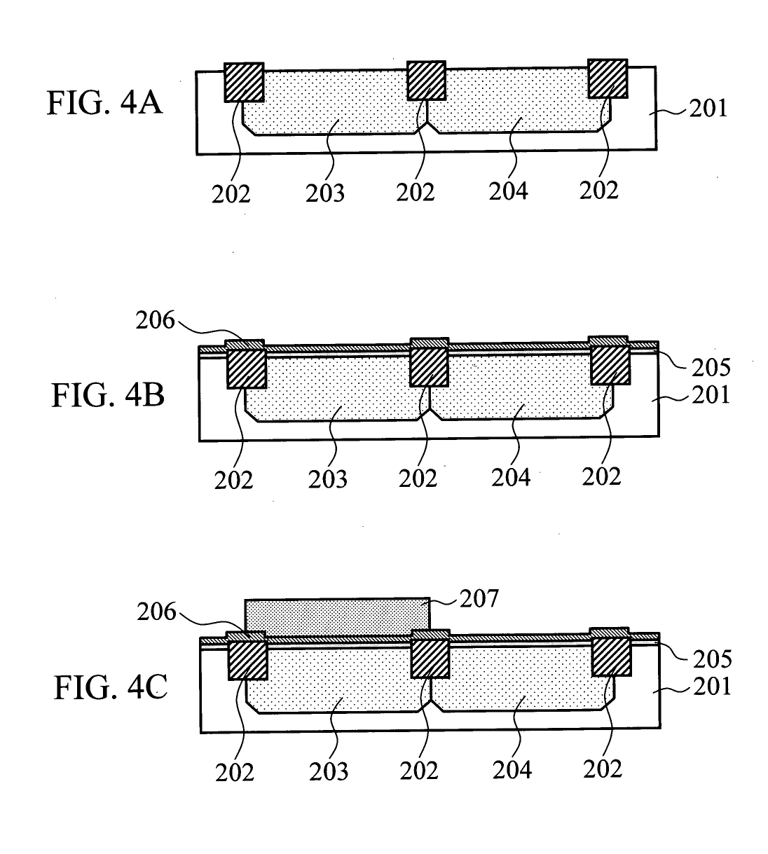

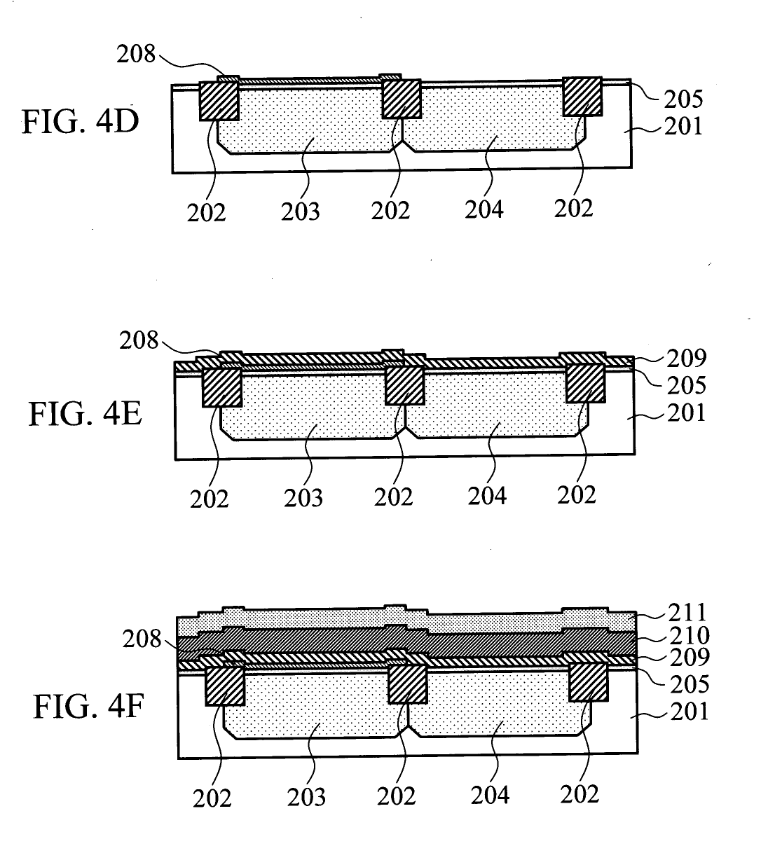

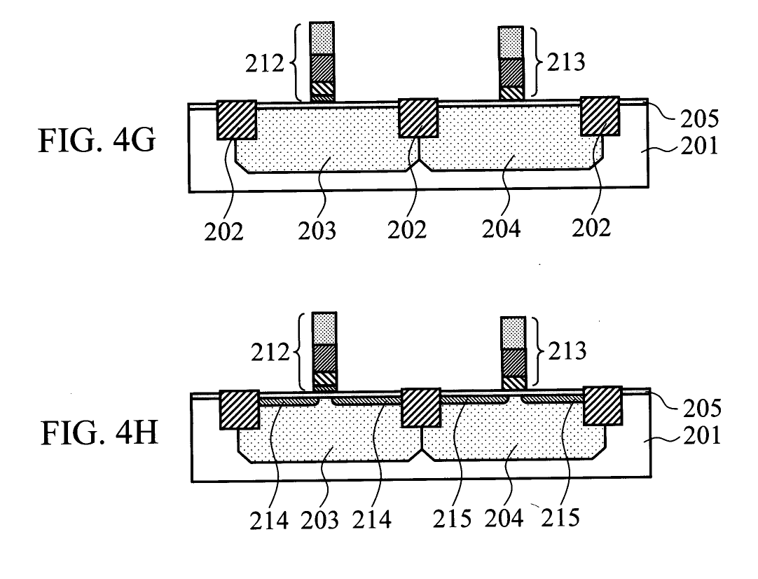

FIGS. 4A through 4H are step sectional views representing a part of the forming process of the CMISFET according to the embodiment of the invention.

First, as shown in FIG. 4A, an element separation area 202, n-type well 203 and p-type well 204 are formed on the surface of the silicon substrate 201.

Then, as shown in FIG. 4B, a gate insulating film 205 and a first metal 206 for the gate electrode of p-type MOSFET are deposited. The gate insulating film 205 may be made of HfO₂, for example. The first metal 206 may be made of TiNₓ, for example.

Next, SiO₂ film is deposited on the whole surface of the wafer by a CVD method, for example, and the SiO2 film is patterned by using a mask pattern (not shown) for the p-type well, and thus, the hard mask 207 is formed as shown in FIG. 4C.

Next, the first metal 206 on the p-type well 204 is removed by using the hard mask 207 as a etching mask, and then the hard mask 207 is removed. Thus, as shown in FIG. 4D, the part of the first metal 208 is left only on the n-type well 203.

Then, as shown in FIG. 4E, the second metal 209 for the gate electrode of the n-type MOSFET is deposited on the whole surface of the wafer. The second metal 209 may be made of ZrN_{y}, for example. In this step, the second metal is deposited so that the nitrogen content of the second metal 209 becomes higher than the nitrogen content of the first metal 206.

Next, as shown in FIG. 4F, a tungsten film 210 and a mask film 211 are deposited on the whole surface of the wafer in this order. The mask film 211 has a role as a hard mask for the gate pattering process, and it may consist of silicon nitride. The tungsten film 210 and the mask film 211 also have a role as a mask for an ion implantation which is performed after forming the gate electrodes.

Then, as shown in FIG. 4G, the gate electrode 212 for the p-type MOSFET and the gate electrode 213 for the n-type MOSFET are formed by using a photolithography technique.

Next, as shown in FIG. 4H, the source/drain areas 214 of the p-type MOSFET and the source/drain areas 215 of the n-type MOSFET are formed by performing an ion implantation using the gate electrodes 212 and 213 as masks. Then, the impurities implanted into the source/drain areas 214 and 215 are electrically activated. Then, the fabrication of the CMISFET is completed by forming the interlayer insulating films and the wirings using the conventional technique.

In the above-explained manufacturing method, it is necessary to etch the first metal 206 and the second metal 209 selectively with regard to the gate insulating film 205. As the etchant to etch these metals selectively with regard to the gate insulating films made of HfO₂, HfSiOₓ or HfSiON, the following solutions can be used:

| Metal/gate insulating film | etchant for the metal |
|---|---|
| TiN/HfO₂ | H₂O₂ solution |
| TiN/HfSiOₓ | H₂O₂ solution |
| TiN/HfSiON | H₂O₂ solution |
| TiN and ZrN/HfO₂ | mixed solution of H₂O₂ and H₂SO₄ |
| TiN and ZrN/HfSiOₓ | mixed solution of H₂O₂ and HCl |
| TiN and ZrN/HfSiON | mixed solution of H₂O₂ and NH₃ |
| ZrN/HfO₂ | solution including HF |

The gate electrode of the first condition and the gate electrode of the second condition (FIGS. 2 and 3) can be formed sequentially by using any of the above-mentioned etchants. Further, in addition to the above-mentioned manufacturing method where the gates are formed by etching (etched gate method), the gate electrodes of the CMISFETS according to the embodiment of the invention may be fabricated by using damascene (replacement) gate method as will be explained in detail later.

Hereinafter, by referring to the experiment executed by the inventor, the semiconductor apparatus relating to the embodiment of the present invention will be explained more in detail.

Firstly, the inventor produced MISFETs having HfSiOn as a material of a gate insulating film by way of trial and examined the one to be used as a gate electrode material.

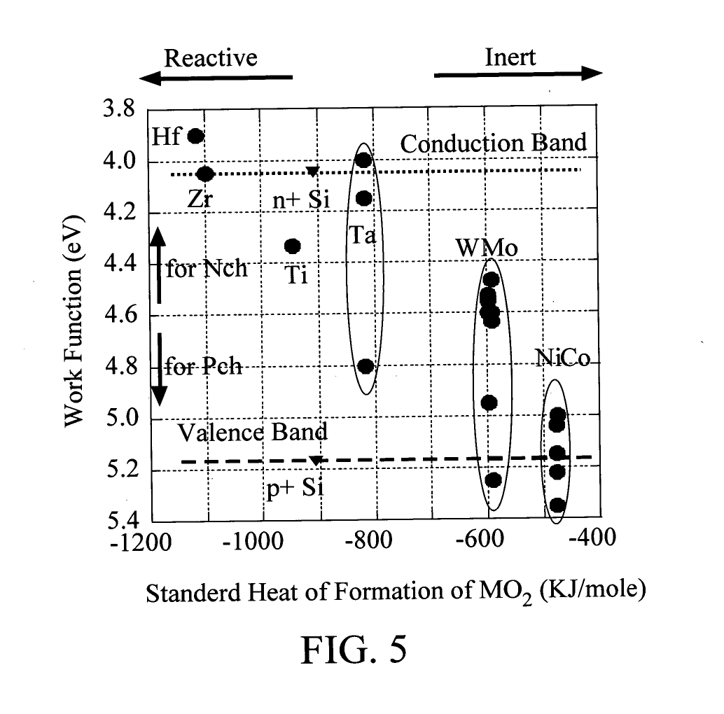

FIG. 5 is a graph showing the work functions of several metals plotted as a function of the heat of formation of oxide thereof. When only the work function is considered, the metals close to the dashed line on the upper side of the drawing are suitable for a gate electrode of n-type MISFET and the metals close to the dashed line on the lower side are suitable for a gate electrode of p-type MISFET. However, to satisfy the various characteristics required for the transistor, the characteristics of the interface between the gate electrode and the high-k material must be considered.

The heat of formation of oxide of a metal is a parameter suitable as an indication representing the reactivity of the metal to oxygen. As the heat of formation is greater (that is, approaching the left in FIG. 5), the metal is apt to react to an oxide such as the high-k material. FIG. 5 shows that the metals suitable for p-type MISFET are chemically stable, while the metals suitable for n-type MISFET are highly reactive to oxygen. Therefore, the inventor executed the systematic experiment on effects of the reactivity of metals on characteristics of MISFET and found a suitable metal as a gate metal. Hereinafter, the experiment executed by the inventor will be explained.

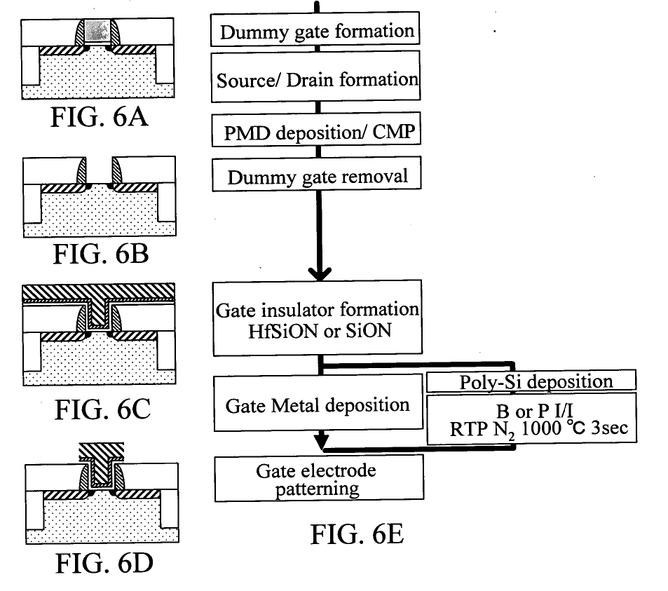

FIG. 6A through 6D are step sectional views representing the forming process of the MISFET produced by way of trial in this experiment and FIG. 6E is a flow chart representing the forming process. In this experiment, the so-called “replacement gate process” is adopted. The process, as shown in FIG. 6E, forms a dummy gate, forms a source/drain area (FIG. 6A), executes active annealing, removes the dummy gate (FIG. 6B), and forms a gate insulating film and a gate electrode (FIGS. 6C and 6D). According to this method, the thermal budget after formation of the gate structure is low, so that a highly reactive metal as a gate electrode material can be used.

As a gate insulating film, thin HfSiOₓ film with a thickness of 3 nm is deposited by the MOCVD (metal-organic chemical vapor deposition) method on thin SiO₂ film with a thickness of 0.7 nm formed by wet oxidation. O₃ treatnment and NH₃ nitriding treatment are subsequently carried out after the deposition of HfSiOₓ to decrease the concentration of the impurity such carbon in the film. Further, for comparison, gate insulating films using SiON are formed.

As a gate electrode material, Ti, TiN, Ta, TaN, Mo, MoN, Zr, and ZrN and n⁺-type polysilicon and p⁺-type polysilicon are used. Ti and TiN, by the CVD method using TiCl4, are formed respectively at 450 degrees centigrade and 600 degrees centigrade. Ta and Mo are formed by the sputtering method. TaN, MoN, and ZrN are formed respectively by the reactive sputtering method. To form a polysilicon gate, a polysilicon thin film is formed, and then P⁺ or B⁺ ions are implanted, and RTA (rapid thermal annealing) is executed at 1000 degrees centigrade for 3 seconds. Further, the polysilicon thin film is wired and then is annealed at 400 degrees centigrade for 30 minutes.

For the MISFETs fabricated by way of trial like this, the Vg (gate voltage)−Id (drain current) characteristic, Vg−Ig (gate current) characteristic, and C-V characteristic are measured. The EOT (equivalent oxide thickness) and flat band voltage V_{-fb} are calculated by NCSU−CVC modeling.

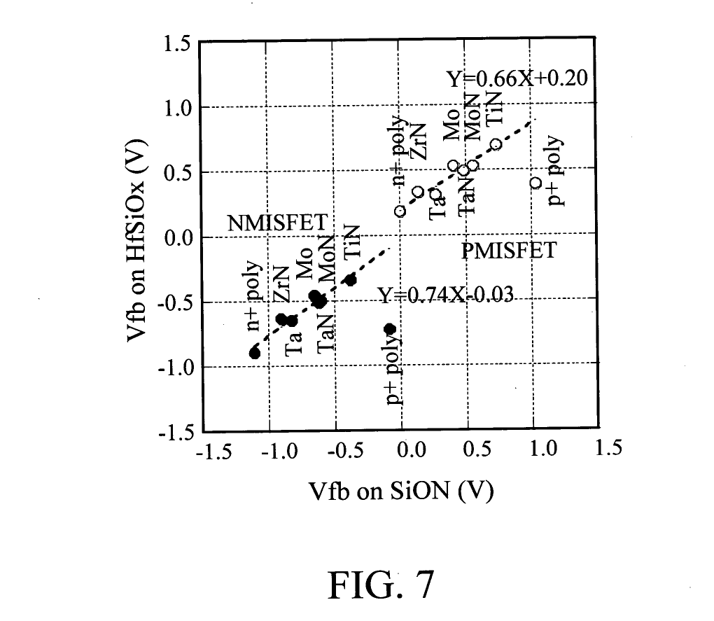

FIG. 7 is a graph showing the relationship between V fb of MISFET using HfSiON and V fb of MISFET using SiON. When p+ polysilicon is excluded, between MISFET using SiON and MISFET using HfSiON, V fb shows an almost linear relationship. The difference in the work function between the metals is almost equal to the V fb difference of MISFET using SiON.

The dashed lines shown in FIG. 7 are the approximate lines obtained by the method of least squares excluding p⁺-type polysilicon. The inclination of each of the dashed lines shown in FIG. 7 is smaller than 1. Namely, with respect to the difference between V fb of the metals and V fb of n⁺-type polysilicon, it is found that the one of MISFET using HfSiON is smaller than the one of MISFET using SiON. Further, the similar trend is seen in a case that HfO₂ is used in place of HfSiON as a material of the gate insulating film.

In FIG. 7, p⁺-type polysilicon is greatly dislocated, though this is a phenomenon observed generally when a HfO₂ based gate insulating film is used.

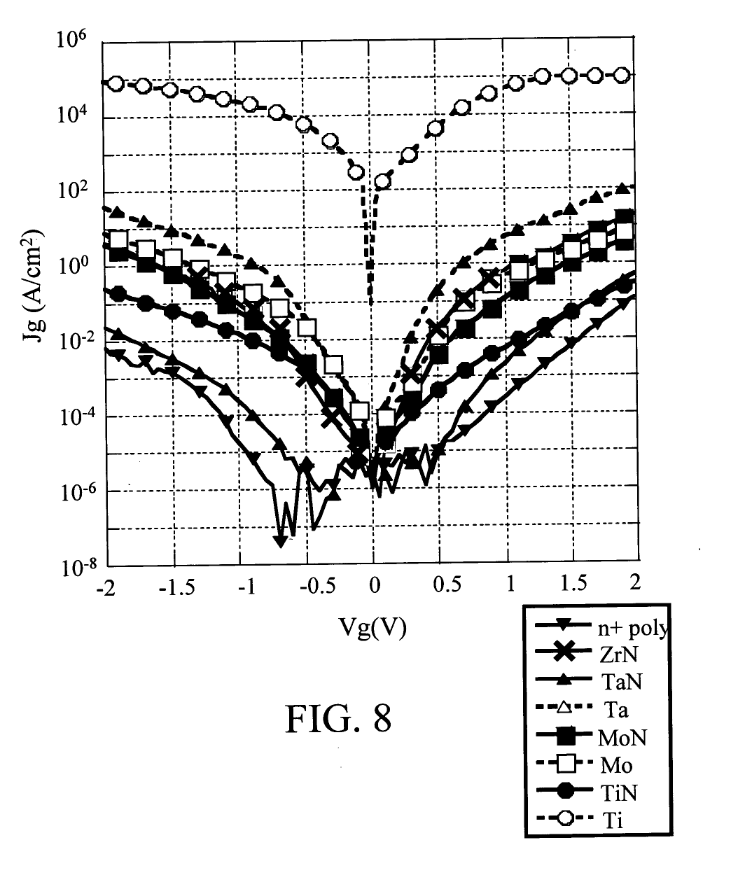

FIG. 8 is a graph showing the gate leak current (Jg) of n-type MISFET using HfSiON. It is found that the gate leak current Jg is rapidly increased in the order of Mo, Ta, and Ti. Particularly, in the n-type MISFET using the Ti gate, the gate leak current Jg is too large to measure the C-V characteristic correctly. This increasing order of the gate leak current well conforms to the reactivity (that is, the heat of formation of oxide of the metal) of the gate electrode material. On the other hand, when the nitrides of the metals are used as a gate electrode, the reactivity can be reduced.

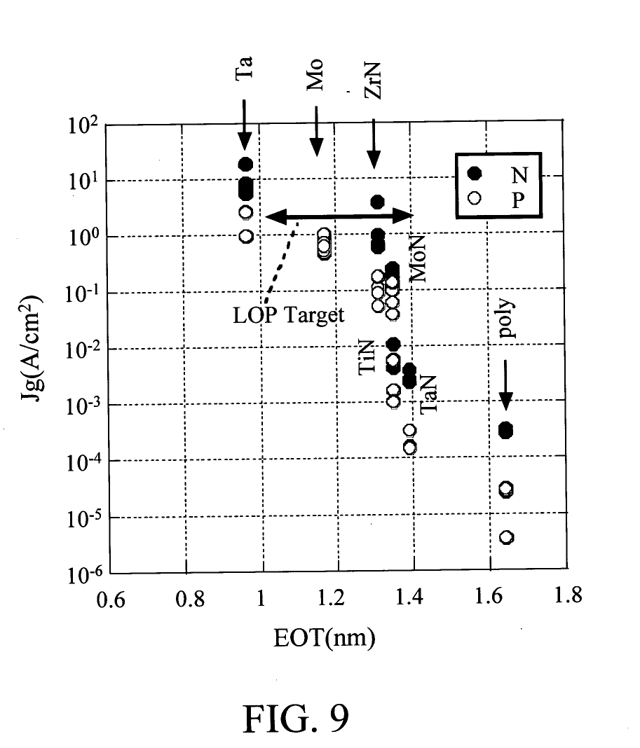

FIG. 9 is a graph showing the relationship between the EOT and the gate leak current Jg of the MISFET using HfSiON. Here, the gate leak current Jg is measured at the gate voltage Vg of 1 V (in n-type FET) or −1 V (in p-type FET). The drawing shows that in a case of a highly reactive metal such as Mo or Ta, the EOT is reduced. An increase in the gate leakage current observed in the MISFETs using these metals is caused by this reduction in the EOT. On the other hand, when nitrides of these metals are used, the reactivity is reduced, so that the reduction in the EOT can be suppressed. In the nitride gate, the EOT is smaller by 0.25 to 0.3 nm or so than that of polysilicon.

Among the data shown in FIG. 9, the gate leak current when the metallic nitride is used as a gate electrode satisfies the target value in the 65-nm LOP (low operation power).

From the results of the explanation concerning FIGS. 5 to 9, it is found that as a gate electrode material of MISFET, TiN and ZrN are desirable.

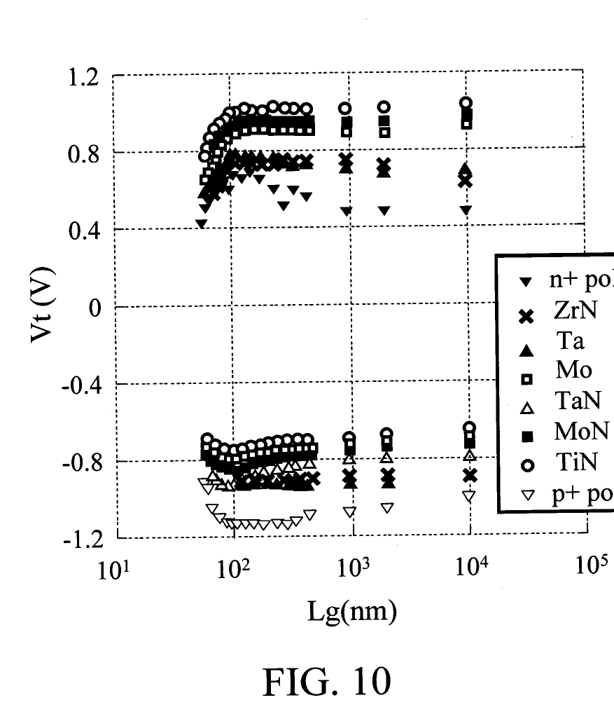

FIG. 10 is a graph showing the roll-off characteristic of the threshold voltage Vₜₕ of MISFET.

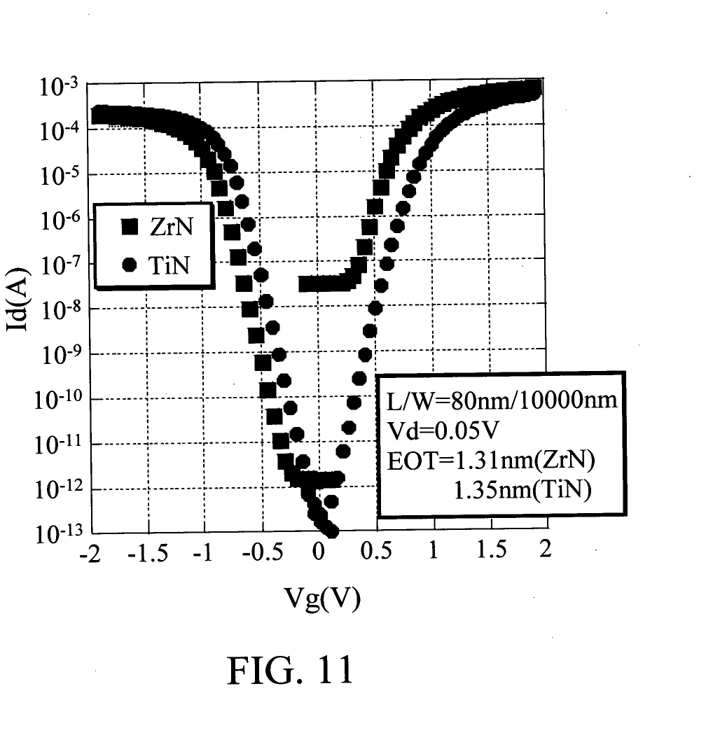

Further, FIG. 11 is a graph showing the subthreshold characteristic when ZrN and TiN are used as a gate electrode of MISFET with a gate length Lg of 80 nm using HfSiON.

FIG. 10 shows that in any metal or a nitride thereof, the symmetry of the threshold voltage Vₜₕ is improved than that when n⁺-type polysilicon and p⁺-type polysilicon are used. Namely, the absolute values of Vₜₕ of n-type MISFET and Vₜₕ of p-type MISFET are close to each other.

When the gate length Lg is 10000 nm, the difference between Vₜₕ of n⁺-type polysilicon and Vₜₕ of ZrN is 0.17 V. The difference can be considered to be able to adjust by optimizing the channel design. In the p-type MISFET using TiN as a gate electrode, the threshold voltage Vₜₕ is lower by 0.35 V than that when p⁺-type polysilicon is used.

Particularly when ZrN is used as a gate electrode of n-type MISFET and TiN is used as a gate electrode of p-type MISFET, the symmetry of the threshold voltage Vₜₕ is increased extremely and ideal characteristics as CMISFET can be obtained.

When the above results are summarized, V fb of the metallic gate type MISFET using HfSiON is the same as that using SION. To obtain a good threshold voltage Vₜₕ, it is desirable to use TiN or ZrN as a gate electrode material. Further, when ZrN is used as a gate electrode of n-type MISFET and TiN is used as a gate electrode of p-type MISFET, it is more desirable because a better threshold voltage Vₜₕ can be obtained.

Further, the gate leak current of FET using a nitride of Ti or Zr is desirable because it fulfills the requirements of LOP of the 65-nm node. When HfSiON is used as a material of the gate insulating film, particularly it is desirable to use TiN or ZrN as a gate electrode.

The experiment for finding desirable matrix materials of the gate electrode is explained above.

Next, the inventor formed several kinds of gate electrodes having different nitrogen contents using these desirable materials and evaluated the crystal structures and C-V characteristics of MISFETs using them.

The gate electrodes produced by way of trial are indicated below.

| | Material | Forming method | Forming condition |
|---|---|---|---|
| Sample 1: | TiN | CVD | 450 degrees Centigrade |
| Sample 2: | TiN | CVD | 650 degrees Centigrade |
| Sample 3: | TiN | Reactive sputtering | Ar:N₂ = 5:2 |
| Sample 4: | TiN | Reactive sputtering | Ar:N₂ = 5:10 |
| Sample 5: | ZrN | Reactive sputtering | Ar:N₂ = 6:2 |
| Sample 6: | ZrN | Reactive sputtering | Ar:N₂ = 6:9 |

Here, as source gas of the CVD method, titanium tetrachloride (TiCl₄) and ammonium (NH₃) are used. Further, in the reactive sputtering, targets of titanium (Ti) or zirconium (Zr) are used and in an atmosphere that argon (Ar) and nitrogen (N₂) are respectively fed at the aforementioned flow rate ratio, they are sputtered. Further, the gate insulating films of MISFET produced by way of trial are formed by oxidizing the silicon surface at 800 degrees centigrade in an oxygen atmosphere (the oxide film thickness is about 10 nm) and then adjusting the thickness thereof by wet etching.

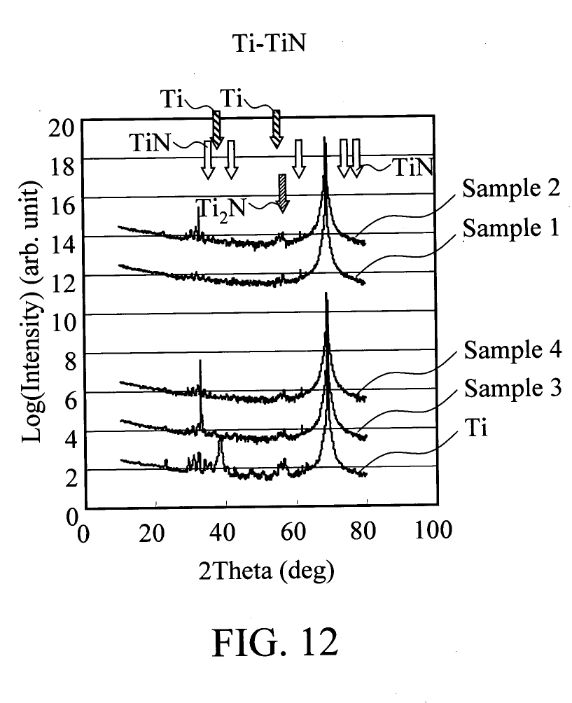

FIG. 12 is a graph showing the results of X-ray diffraction evaluation (XRD) of titanium based samples.

Further, in the drawing, the measurement results of titanium (Ti) are shown for reference. Further, on the upper part of the graph, the diffraction peak positions of Ti, TiN, and Ti₂N are shown respectively by arrows.

With regard to the samples 1, 2 and 3, a clear difference was not observed, and it is considered that theses samples are in a micro-crystalline structure.

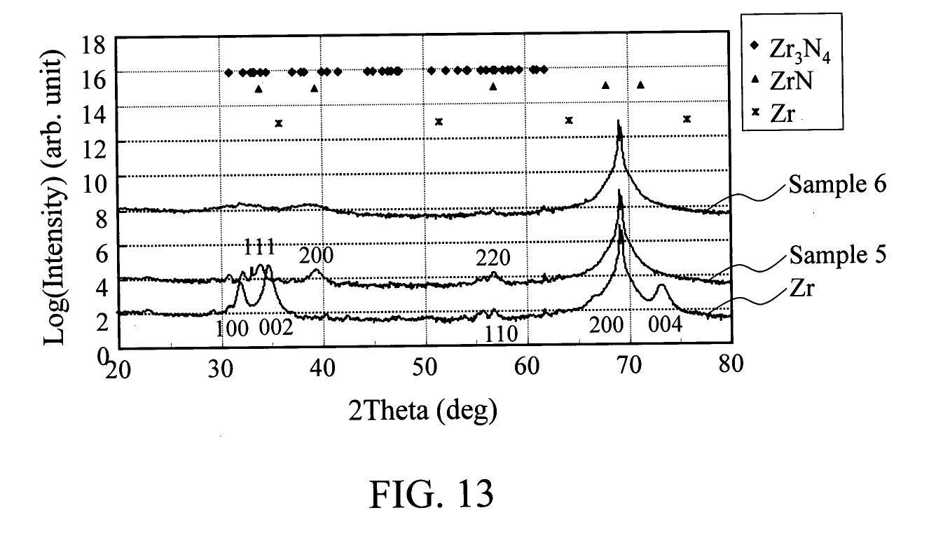

FIG. 13 is a graph showing the results of X-ray diffraction evaluation of zirconium based samples.

Further, in the drawing, the measurement results of zirconium (Zr) are shown for reference. Further, on the upper part of the graph, the diffraction peak positions of Zr, ZrN, and Zr₃N₄ are shown respectively by arrows.

In FIG. 13, when comparing Zr for reference with the sample 5, in the sample 5, the peak of Zr is weak and the peak of ZrN is strongly shown inversely. Further, when comparing the sample 5 with the sample 6, in the sample 6, the peak of ZrN is weak clearly and the peak of Zr₃N₄ is shown slightly. Namely, the nitrogen content of the sample 6 is relatively higher than that of the sample 5, thus it is inferred that the crystal structure is changed.

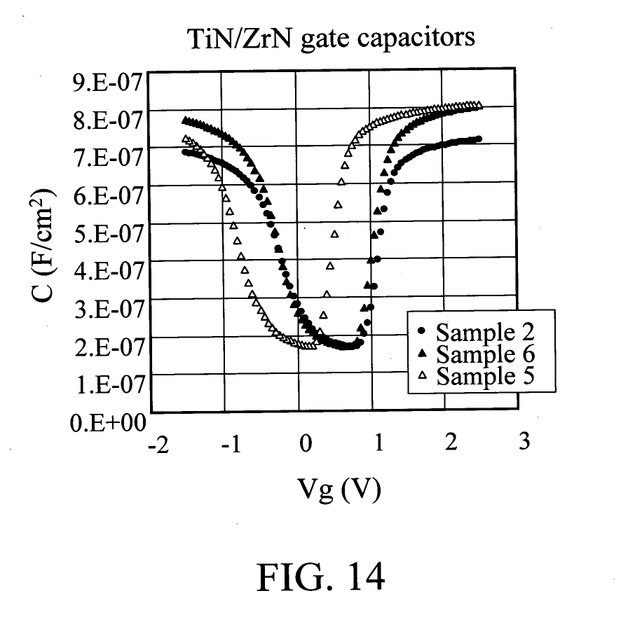

FIG. 14 is a graph showing the C-V characteristic of n-type MISFETs using Zr based gate electrodes. Further, the FETs fabricated by way of trial are equivalent to those having an oxide film thickness Tox of about 5 nm. When comparing the sample 5 with the sample 6, it is found that the flat band voltage V fb of the sample 6 is shifted on the positive side and as the nitrogen content is increased, the work function becomes higher. The shift amount of voltage reaches 0.5 to 0.6 V and it is found that even in the same material based, this voltage shift can be obtained depending on the nitrogen content. Further, also in the Ti based sample 2 by the CVD method, the equivalent C-V characteristic as that of the sample 6 is obtained, so that it is inferred that a similar work function is obtained.

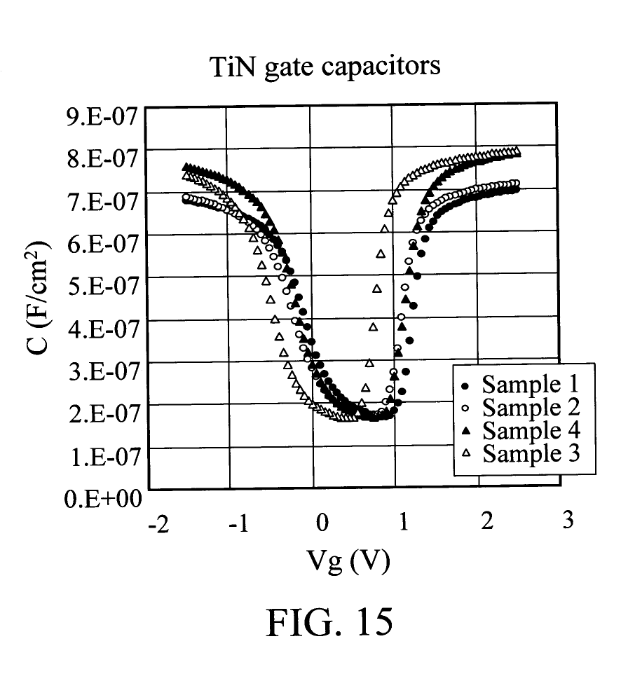

FIG. 15 is a graph showing the C-V characteristic of n-type MISFET using Ti based gate electrodes. Further, the FETs fabricated by way of trial are equivalent to those having an oxide film thickness Tox of about 5 nm. Compared with the sample 3, the voltage of the sample 4 is clearly shifted on the positive side. Namely, it is found that as the nitrogen content is increased, the work function becomes higher. Further, also in the Ti based sample 2 by the CVD method, the equivalent C-V characteristic as that of the sample 6 is obtained, so that it is inferred that a similar work function is obtained.

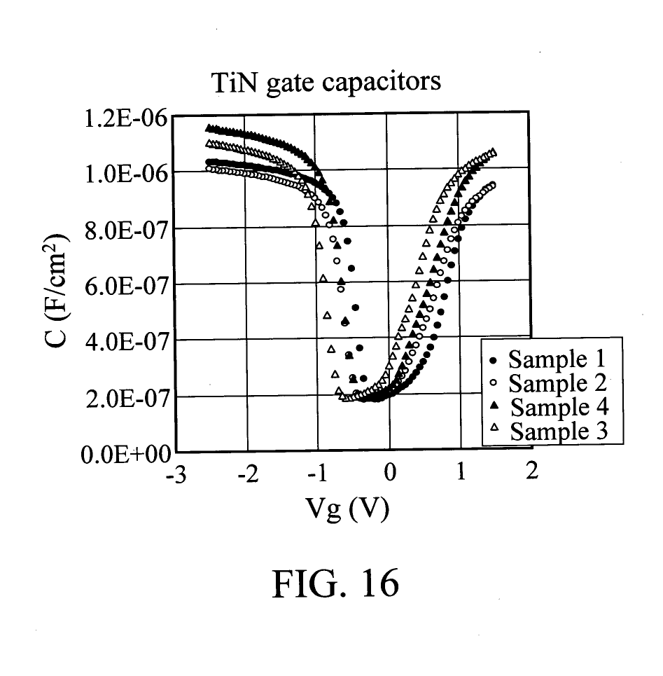

FIG. 16 is a graph showing the C-V characteristic of p-type MISFET using Ti based gate electrodes. Further, the FETs produced by way of trial are equivalent to those having an oxide film thickness Tox of about 3.5 nm. Compared with the sample 3, in the samples 2 and 4, the voltage is shifted on the positive side. Furthermore, it is found that the sample 1 is apt to be shifted more on the positive side than them. Namely, also in this case, it is found that as the nitrogen content is increased, the work function becomes higher.

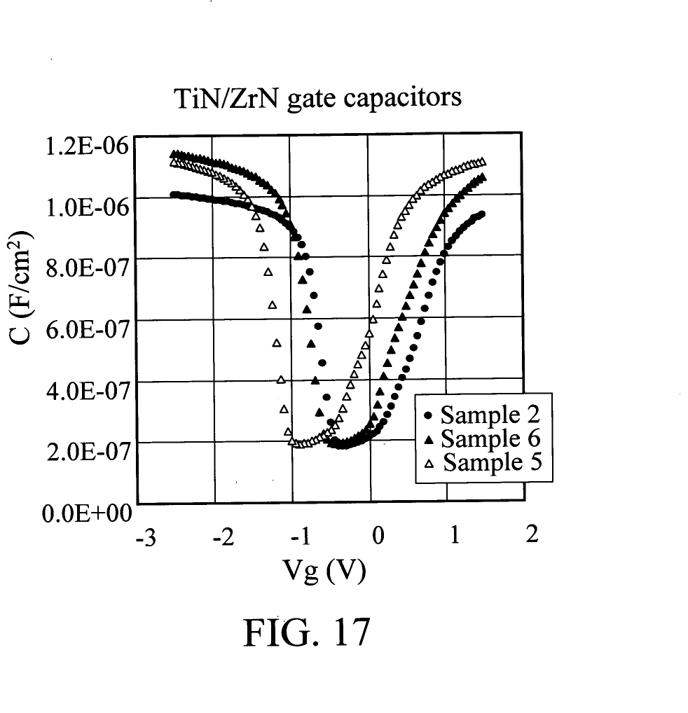

FIG. 17 is a graph showing the C-V characteristic of p-type MISFET using Ti based and Zr based gate electrodes. Further, the FETs produced by way of trial are also equivalent to those having an oxide film thickness Tox of about 3.5 nm. Compared with the sample 5, in the samples 6 and 2, the voltage is shifted on the positive side. Namely, also in this case, it is found that as the nitrogen content is increased, the work function becomes higher. Further, it is found that the voltage shift amount reaches about 0.5 eV.

The results shown in FIGS. 12 to 17 show that even in a Ti based nitride and a Zr based nitride, when the nitrogen content is increased, the threshold voltage Vt and flat band voltage V fb are shifted on the positive side. Even within the range of the aforementioned trial manufacture examples, a voltage shift of about 0.5 to 0.6 V is observed. The reason may be considered that as the nitrogen content is increased, the work function of the gate electrode becomes higher.

The inventor executed a composition analysis on the Ti based samples 1-4 and the Zr based samples 5 and 6 by the RBS (Rutherford Back Scattering).

Table 1 is a list showing the ratios of nitrogen content to the metal content obtained by the RBS.

TABLE 1

| Sample | N/Metal |
|---|---|
| Sample 1 (TiNx) | 1.09 |
| Sample 2 (TiNx) | 1.04 |
| Sample 3 (TiNx) | 0.71 |
| Sample 4 (TiNx) | 1.02 |
| Sample 5 (ZrNx) | 1 |
| Sample 6 (ZrNx) | 1.42 |

Among the Ti based samples 1-4, the ratio of nitrogen of the sample 3 is as low as 0.71, the ratios of nitrogen of the samples 1, 2 and 4 are almost 1. In the case of the Zr based samples 5 and 6, the ratio of nitrogen of the sample 5 is 1, while the ratio of nitrogen of the sample 6 is as high as 1.42.

From these results, in the case of Ti based gate electrodes, it is understood that the ratio of nitrogen (nitrogen/metal) of the gate electrode of the p-type MISFET is preferably set to be greater than 1.43 time of the ratio of nitrogen (nitrogen/metal) of the gate electrode of the p-type MISFET by comparing the sample 3 and the samples 1, 2 and 4. On the other hand, in the case of Zr based gate electrodes, it is understood that the ratio of nitrogen (nitrogen/metal) of the gate electrode of the p-type MISFET is preferably set to be greater than 1.42 time of the ratio of nitrogen (nitrogen/metal) of the gate electrode of the n-type MISFET by comparing the sample 5 and the sample 6. Further, in the case where ZrNₓ is used for the gate electrode of n-type MISFET and TiN_{y} is used for the gate electrode of p-type MISFET, the ratio x of nitrogen of ZrNₓ is preferably set to about 1 like sample 5, and the ratio y of nitrogen of TiN_{y} is also preferably set to about 1 like samples 1, 2 and 4.

As explained above, in the nitrides of Ti and Zr, when the nitrogen content is controlled, the work function thereof can be adjusted. Concretely, when the nitrogen content is increased, the work function can be increased. Therefore, when these metallic nitrides are used as a gate electrode material and moreover, the nitrogen content of the gate electrodes of p-type MISFET is made higher than the nitrogen content of the gate electrodes of n-type MISFET, the threshold voltages of the n-type MISFET and p-type MISFET can be set on the same level. As a result, a CMISFET performing a stable operation can be realized.

According to the present invention, as a material of the gate insulating film, a nitride of a IV a group metal such as Ti or Zr is used, and furthermore the content of the nitrogen is adjusted, thus in a MISFET using a high-k material for a gate insulating film, a semiconductor apparatus in which any of the threshold voltages Vₜₕ of n-type MISFET and p-type MISFET is suppressed can be provided.

As a result, an extremely-fine large-scale integrated semiconductor apparatus represented by a 65-nm node can be realized and it takes great industrial advantage.

The embodiment of the present invention is explained above by referring to the concrete examples. However, the present invention is not limited to these concrete examples.

For example, with respect to the structure and material of each unit of the semiconductor apparatus, the conductive type, impurities, the thin film forming method, and the methods and conditions of oxidization and nitriding, in addition to the aforementioned as the concrete examples, those which are properly added by those who are skilled in the art in the field of the present invention, including the summary of the present invention are all within the scope of the present invention.

Furthermore, semiconductor apparatuses having the elements of the present invention which can be properly changed in design by those who are skilled in the art in the field of the present invention and manufacturing methods thereof are all within the scope of the present invention.

1. A semiconductor apparatus comprising a first semiconductor device and a second semiconductor device, the first semiconductor device including:
a semiconductor layer having a p-type channel area;
an n-type source area, and an n-type drain area;
a first gate insulating film provided on the p-type channel area; and
a first gate electrode provided on the first gate insulating film containing a first metallic element and nitrogen,
the second semiconductor device including:
a semiconductor layer having an n-type channel area, a p-type source area, and a p-type drain area;
a second gate insulating film provided on the n-type channel area; and
a second gate electrode provided on the second gate insulating film containing a second metallic element and nitrogen,
a nitrogen content of the second gate electrode being higher than a nitrogen content of the first gate electrode.

2. A semiconductor apparatus according to claim 1, wherein the first and second metallic elements are IV a group elements.

3. A semiconductor apparatus according to claim 1, wherein the first and second metallic elements are either of Ti and Zr.

4. A semiconductor apparatus according to claim 1, wherein the first metallic element is Zr and the second metallic element is Ti.

5. A semiconductor apparatus according to claim 4, wherein the first metallic element and the second metallic element are Zr, and the second gate electrode includes Zr₃N₄.

6. A semiconductor apparatus according to claim 1, wherein a work function of a material constituting the second gate electrode is higher by 0.4 eV or more than a work function of a material constituting the first gate electrode.

7. A semiconductor apparatus according claim 1, wherein a nitrogen content of the second gate electrode is 1.4 times or more of a nitrogen content of the first gate electrode.

8. A semiconductor apparatus according to claim 1, wherein the first and second gate insulating films contain Hf and O.

9. A semiconductor apparatus according to claim 1, wherein the first semiconductor device and the second semiconductor device form a CMISFET.

10. A semiconductor apparatus according to claim 1, wherein an absolute value of a threshold voltage of the first semiconductor device and an absolute value of a threshold voltage of the second semiconductor device are substantially the same.

11. A semiconductor apparatus comprising a first semiconductor device and a second semiconductor device,
the first semiconductor device including:
a semiconductor layer having a p-type channel area;
an n-type source area, and an n-type drain area;
a first gate insulating film provided on the p-type channel area; and
a first gate electrode provided on the first gate insulating film containing a first metallic element and nitrogen,
the second semiconductor device including:
a semiconductor layer having an n-type channel area, a p-type source area, and a p-type drain area;
a second gate insulating film provided on the n-type channel area; and
a second gate electrode provided on the second gate insulating film containing a second metallic element and nitrogen,
the first metallic element and the second metallic element being different.

12. A semiconductor apparatus according to claim 11, wherein the first metallic element is Zr and the second metallic element is Ti.

13. A semiconductor apparatus according to claim 11, wherein a nitrogen content of the first gate electrode and a nitrogen content of the second gate electrode are substantially the same.

14. A semiconductor apparatus according to claim 11, wherein a work function of a material constituting the second gate electrode is higher by 0.4 eV or more than a work function of a material constituting the first gate electrode.

15. A semiconductor apparatus according to claim 11, wherein the first semiconductor device and the second semiconductor device form a CMISFET.

16. A semiconductor apparatus according to claim 11, wherein an absolute value of a threshold voltage of the first semiconductor device and an absolute value of a threshold voltage of the second semiconductor device are substantially the same.

17. A manufacturing method of a semiconductor apparatus having a first semiconductor device in which a first gate electrode is provided on a p-type channel area via a first gate insulating film and a second semiconductor device in which a second gate electrode is provided on an n-type channel area via a second gate insulating film, comprising:
forming the first gate electrode on the first gate insulating film by feeding a first metallic element and nitrogen; and
forming the second gate electrode on the second gate insulating film by feeding a second metallic element and nitrogen,
the step of forming the first gate electrode and the step of forming the second gate electrode being performed so that a nitrogen content of the second gate electrode becomes higher than a nitrogen content of the first gate electrode.

18. A manufacturing method of a semiconductor apparatus according to claim 17, wherein the first and second metallic elements are IV a group elements.

19. A manufacturing method of a semiconductor apparatus according to claim 17, wherein a work function of a material constituting the second gate electrode is higher by 0.4 eV or more than a work function of a material constituting the first gate electrode.

20. A manufacturing method of a semiconductor apparatus according claim 17, wherein a nitrogen content of the second gate electrode is 1.4 times or more of a nitrogen content of the first gate electrode.
